(19) United States
(12) Patent Application Publication
(10) Pub. No.: US 2023/0076449 A1
(43) Pub. Date: Mar. 9, 2023

(54) RUGGEDIZED DV-LED DISPLAY SYSTEMS AND MODULES, AND METHODS OF MANUFACTURING DV-LED DISPLAYS

(71) Applicant: PLANAR SYSTEMS, INC., Hillsboro, OR (US)

(72) Inventors: Pete LUTY, Portland, OR (US); Seth KREBSBACH, Vancouver, WA (US); Garrett EWELL, Madras, OR (US)

(21) Appl. No.: 17/904,674

(22) PCT Filed: Feb. 19, 2021
(86) PCT No.: PCT/US2021/018923

§ 371 Date: Aug. 19, 2022

Related U.S. Application Data
(60) Provisional application No. 62/979,280, filed on Feb. 20, 2020.

(51) Int. Cl. H01L 25/075; H05K 1/18; H05K 3/28

(52) U.S. Cl. CPC H01L 25/0753; H05K 1/181; H05K 3/284; H05K 2201/10106; H05K 2201/10977; H05K 2201/10128

(57) ABSTRACT

A ruggedized direct-view LED display system (100) includes a bonding matrix (215) that helps secure an array of LED chips (205) to a printed circuit board (PCB) (210). The bonding matrix may consist of an epoxy or other resin deposited on the surface (310) of the PCB after soldering the LED chips to the PCB. The bonding matrix has a thickness that is less than the thickness of the LED chips so that light-emitting outer portions (415) of the LED chips are not covered by the bonding matrix material. A method of forming the bonding matrix is also disclosed, including depositing bonding matrix material onto the PCB between the LED chips using nozzles or needles, optionally wicking excess bonding matrix material, and optionally degassing the bonding matrix material before curing it to form the bonding matrix.

### RELATED APPLICATION

This application claims the benefit under 35 U.S.C. § 119(e) of U.S. Provisional Patent Application No. 62/979,280, filed Feb. 20, 2020, which is incorporated by reference.

### BACKGROUND

Electronic display systems, such as indoor and outdoor display walls, may use surface mounted device (SMD) light emitting diode (LED) chips to output light that forms displayed content. In such systems, SMD LED chip contacts can be soldered to a printed circuit board (PCB), providing electrical connection between each chip and the PCB. Each pixel of the display may be emitted directly by each discrete SMD, and these types of displays are therefore sometimes referred to as Direct-view LED displays or DV-LED displays. The solder electrically connecting each LED chip to the PCB mechanically secures each chip to the PCB. However, physical impact on a soldered SMD LED chip can dislodge the chip, compromising the connection between each contact and the PCB and increasing the likelihood of chip failure. SMD LED chips may be subject to such structural damage during display assembly, installation, service, and field use.

Strengthening the bond between SMD LED chip contacts and a PCB has been attempted. For instance, previous attempts include applying an epoxy layer over the entire PCB such that each soldered chip is fully covered and encapsulated by the epoxy layer. These previous attempts may improve bonding, but the present inventors have recognized that drawbacks exist. For instance, applying a fully encapsulating epoxy layer can be time consuming and costly. The fully encapsulating epoxy layer may cure unevenly, which introduces unwanted thickness inconsistencies across the layer, which may cause image distortion. Moreover, the fully encapsulating epoxy layer may create a glossy finish across the display that can be undesirable to viewers and cause unwanted reflections. The fully encapsulating epoxy layer may also cause other optical defects, such as refraction at seams between adjacent display modules, which can reduce apparent uniformity of the display illumination across the array of modules forming the display. The encapsulating epoxy may also attenuate the brightness and sharpness of the display. Repairing a malfunctioning chip that is fully encapsulated by an epoxy layer can also be challenging. Such repairs may be time consuming and difficult to perform in the field because a milling machine may be required to extract the malfunctioning chip and expose the PCB for installing a replacement chip.

It is known to coat LED-carrying PCBs with a very thin layer of a polymer resin (on the order of microns) to shield the PCB and LED chip contacts against the corrosive effects of humidity, but such a thin layer of resin does not appreciably strengthen the bonds between each LED chip and the PCB.

The present inventors have recognized that fully encapsulating SMD LED chips on a PCB can increase fabrication time, introduces undesirable optical characteristics, and makes repair of failed LEDs challenging. The present inventors have recognized the need for improved ruggedized DV-LED displays and methods for their manufacture.

### BRIEF DESCRIPTION OF THE DRAWINGS

FIG. 1 is a front schematic view of a display system according to a preferred embodiment, made up of display cabinets formed of multiple display modules.

FIG. 2 is an isometric, enlarged detail schematic view of a single display cabinet of the display system of FIG. 1, showing four display modules of the cabinet and illustrating details of the modules, and a cured bonding matrix securing SMD LED chips onto PCBs of each module.

FIG. 3 is an isometric, enlarged schematic view of one of the display modules of FIG. 2 shown prior to deposition of bonding matrix material which forms the bonding matrix.

FIG. 4 is a cross-sectional detail view at 4-4 in FIG. 2, showing a bonding matrix on a PCB surface of a display module.

FIG. 5 is an exploded view of display modules of FIG. 2, showing a surface where adjacent modules are mated.

FIG. 6 is a flow chart describing a process of forming a bonding matrix on a PCB surface of a display module.

### DETAILED DESCRIPTION OF PREFERRED EMBODIMENTS

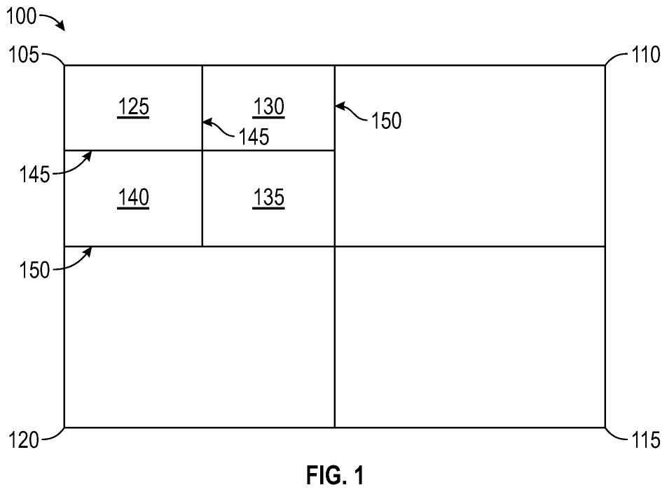

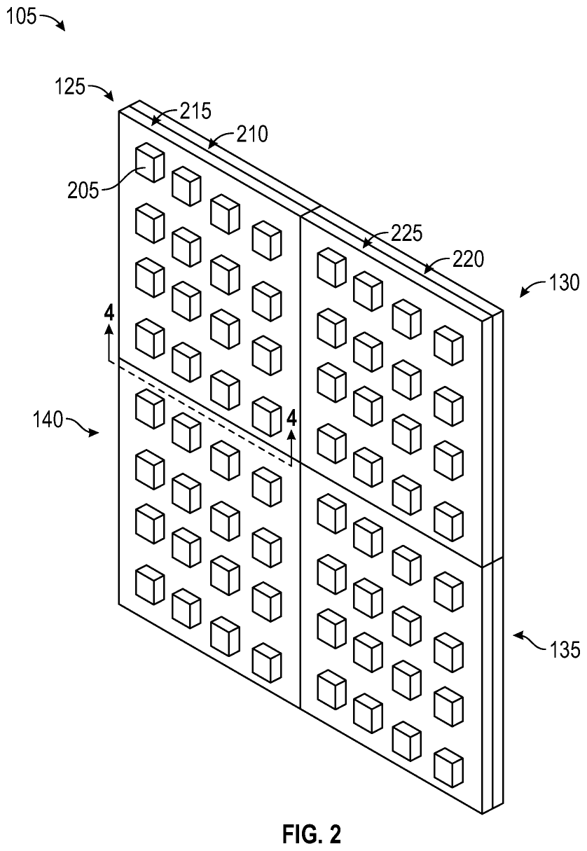

FIG. 1 Illustrates a display system 100 according to a preferred embodiment, which may also be referred to as a display wall. Display system 100 is formed by an exemplary arrangement of display cabinets 105, 110, 115, and 120. Between the cabinets 105, 110, 115, 120, vertical and horizontal seams 150 are formed where cabinets 105,110, 115, 120 are abutting or adjacent each other. Each display cabinet 105, 110, 115, 120 comprises one or more display modules, which may also be referred to as display panels or display tiles. In the embodiment shown, display cabinet 105 is formed by four display modules 125, 130, 135, and 140, each having an array of SMD LED chips 205 (shown in FIG. 2) attached to a PCB 210 (FIG. 2). In other embodiments, display system 100 may be formed by a different number of cabinets, and each of the cabinets may be formed by a different number of modules. For example, each cabinet may be formed by four to eight display modules, and display system 100 may be formed of two or more cabinets, such as 10, 12, 16, 18, 20, 40 or more cabinets. Between modules, vertical and horizontal seams 145 are formed. In some embodiments, cabinets 105, 110, 115, and 120 exhibit a matte finish on their displayable surface.

FIG. 2 is an isometric, enlarged schematic detail view of display cabinet 105 of display system 100. In the embodiment shown, cabinet 105 includes four display modules 125, 130, 135, and 140, each having an array of SMD LED chips 205 mounted on a PCB 210 of the module. In some embodiments, SMD LED chips 205 are arranged according to a specified pitch, defining a consistent distance between adjacent LED chips 205 in each row and column of the chips 205. The pitch is measured from LED center to LED center and may be set to a value from about 0.7 mm to about 2.5 mm, for example. It should also be noted that while a four by four array of SMD LED chips 205 is shown on each of the display modules 125, 130, 135 and 140, this array is a simplified schematic representation for ease of illustration, and in practice each module may include a much greater quantity of LED chips in the array. It should also be noted that in practice, LED chips may be evenly spaced consistently across the entire display (e.g., across modules, as well as across seams 145 between modules and across seams 150 between cabinets).

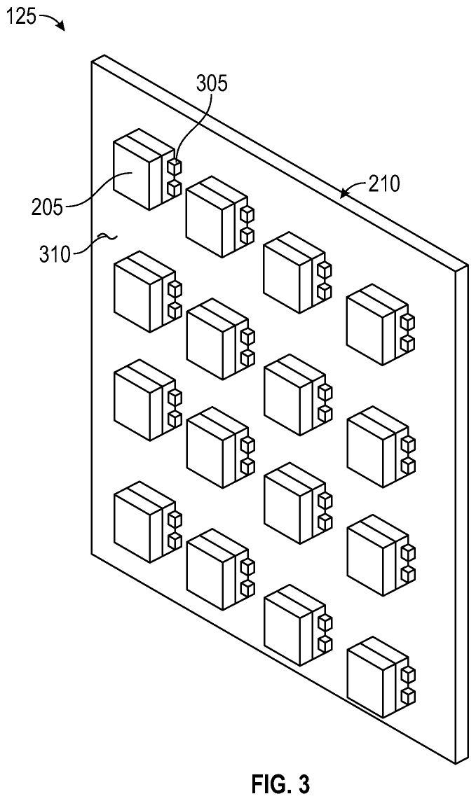

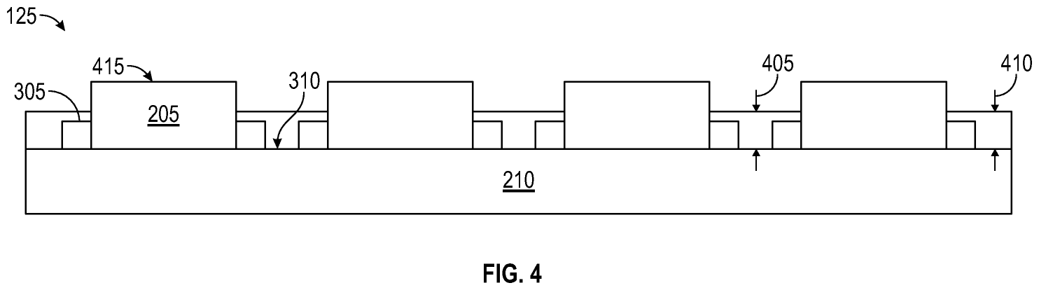

Each SMD LED chip 205 has at least one electrical contact 305 (shown in FIG. 3) that is soldered to an electrical contact (not shown) on an outer major surface 310 (FIG. 3) of PCB 210. A bonding matrix 215 is also deposited onto the surface 310 to provide structural support for chips 205 and to inhibit chips 205 and their solder connections from being dislodged from PCB 210 due to physical impacts. In the embodiment shown, bonding matrix 215 is thinner than the thickness of chips 205, so that the bonding matrix 215 leaves outer portions of each chip 205 exposed. The exposed portions of each chip 205 include a light emitting outer portion 415 (FIG. 4) facing away from the surface 310 of PCB 210. Bonding matrix 215 may also be referred to as a partially encapsulating layer, a bonding web, or a matrix encapsulating layer. In the embodiment shown, each chip 205 is partially encapsulated by bonding matrix 215 and the surface of PCB 210 is covered.

In some embodiments, bonding matrix 215 is formed by curing a bonding matrix material such as epoxy resin, or primarily epoxy resin, formed from a mixture of co-reactants. For example, the epoxy may be yellowing resistant, ultraviolet (UV) resistant, and/or heat resistant. In other embodiments, bonding matrix 215 may be formed of other substances, such as other types of resins, polymers, urethanes, and other cured materials, preferably those that have a relatively low viscosity when uncured and which, when cured, form strong adhesive bonds with PCB 210 and LED chips 205. In some embodiments, bonding matrix 215 may be formed of a material that is cured using UV light. In some embodiments, curing of the bonding matrix material may be performed by air curing, thermal curing, additive curing, light curing, or a combination of these curing techniques, for example. In some embodiments, a thinner or reducer is added to the uncured resin, epoxy or other bonding matrix material to decrease its viscosity and improve the ability of the bonding matrix material to uniformly distribute under and around LEDs and across the PCB. Suitable thinners and/or reducing agents may include isopropyl alcohol; epoxy thinner, such as EPIC™ epoxy thinner sold by Smooth-On, Inc.; and lacquer thinner comprising one or more of ethers, alcohols, alkyl esters such as butyl or amyl acetate, ketones such as acetone or methyl ethyl ketone, and aromatic hydrocarbons like toluene, xylene or ethylbenzene. In some embodiments, a colorant such as a black pigment, black dye, or other color of pigment or dye, may be added to the resin, epoxy, or other bonding matrix material to improve perceived contrast or otherwise improve the visual appearance of the display system 100. In the embodiment shown, bonding matrix 215 fully covers and encapsulates the electrical contacts 305 (FIG. 3) of each chip 205, while not coating the light emitting outer portions 415 (FIG. 4) of the chips 205. Thus, the addition of a black pigment or other colorant in the bonding matrix may have the benefit of masking electrical contacts 305 and certain other reflective portions of LED chips 205 and PCB 210 that can result in image degradation, suboptimal black levels, or reduced contrast ratio in the display system 100.

FIG. 4 is a cross-sectional detail view of module 125 taken at section line 4-4 in FIG. 2. FIG. 4 illustrates a thickness 405 of bonding matrix 215 between adjacent chips 205 on PCB 210, and a thickness 410 of bonding matrix 215 in an edge region of the PCB 210 of module 125. The bonding matrix 215 may be deposited to have a selected uniform thickness in the range of between 5% to 80% of the height of chips 205, measured from the surface 310 of PCB 210 to the vertex of each chip 205 at the light emitting outer portion 415. In some embodiments, the thickness of the bonding matrix 215 may deposited to have a uniform thickness in the range of about 40% to about 50% of the height of each chip 205, measured from the surface 310 of PCB 210 to the vertex of each chip 205. The degree of uniformity or planarity may be on the order of a few thousands of an inch across the entire area of the module 125, for example less than 0.01 inch. In the embodiment shown, thicknesses 405 and 410 are about the same and therefore about equal (e.g., exactly equal or close to equal), varying less than a threshold such as for example less than 0.001 inch or 0.01 inch therebetween. For example, the thickness of the bonding matrix 215 may vary less than 10% across the entire area of module 125, or more preferably less than 5% or less than 1%.

Bonding matrix 215 improves retention between each contact 305 of chip 205 and the surface 310 of PCB 210, and provides adhesion between a body portion or portions of each chip 205 and surface 310. Bonding matrix 215 may also reduce the chance of damage to one or more chips 205, including by protecting contacts 305 and/or solder from being damaged. Bonding matrix 215 does not fully encapsulate each chip 205. Accordingly, a front light emitting surface 415 of each chip is unobstructed by bonding matrix 215. In the embodiment shown, bonding matrix 215 also provides adhesion between chips 205 and PCB 210 and between side surfaces of adjacent chips 205. In some embodiments, bonding matrix 215 may seal PCB surface 310 and the bottom portion of LED 205 against environmental moisture. In some embodiments, bonding matrix 215 bonds around the outer perimeter of chips 205. In some embodiments, bonding matrix 215 penetrates underneath part (e.g., around an underneath perimeter of a chip) or all of one or more chips 205.

In some embodiments, bonding matrix 215 provides improved access to a malfunctioning chip 205 because the chip is not fully encapsulated by matrix 215 and may thereby be more accessible. For example, in some embodiments, repair of a malfunctioning chip 205 may entail extracting the chip with a scalpel rather than a milling machine, which allows for in-the-field repair. After extraction of the malfunctioning chip, a replacement chip may be soldered in its place to PCB 210 and parts of matrix 215 removed during chip extraction may be replaced.

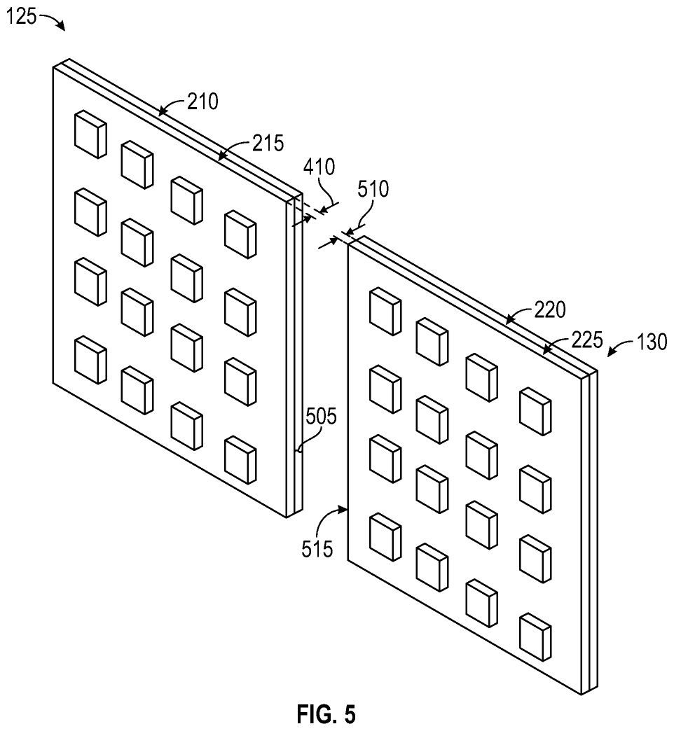

FIG. 5 is an exploded view showing display modules 125 and 130 of FIG. 2 and an outer edge surface 505 of PCB 210 that is mated to a corresponding outer edge surface 515 of PCB 220 when forming cabinet 105. In the embodiment shown, when depositing bonding matrix material that forms bonding matrix 215 on surface 310 of PCB 210, outer edge surface 505 is masked to avoid bonding of the bonding matrix material to the outer edge surface 505. The corresponding outer edge surface 515 of PCB 220 is similarly masked. In some embodiments, the masking is performed by applying removable self-adhesive tape to outer edge surface 505. In some embodiments, the masking is performed by applying a cover or framing to outer edge surface 505. The masking is removed after curing of the boding matrix 215 leaving clean edge surfaces 505, 515 which are abutted when modules 125 and 130 are mated together or ganged together to form the cabinet. In some embodiments, improved mating may occur, which may reduce the appearance of seams 145 between modules. In some embodiments, the appearance of seams 150 between cabinets may be similarly reduced when mating cabinets together.

In the embodiment shown, module 130 has a thickness 510, which corresponds to thickness 410 of module 125. In the embodiment shown, the bonding matrices 215 and 220 are formed on their respective modules 125 and 130 such that thicknesses 410 and 510 are about equal, where any difference is less than a threshold, such as less than 0.001 inch or 0.01 inch. For example, in some embodiments, having thicknesses 410 and 510 about equal may reduce the appearance of seams 145 between adjacent modules. In some embodiments, the appearance of seams 150 between adjacent cabinets may be similarly reduced.

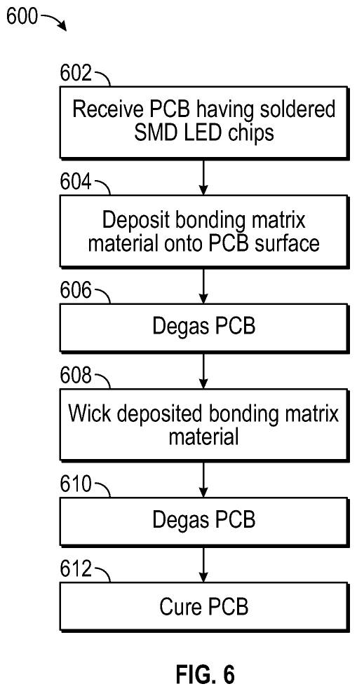

FIG. 6 is a flow chart describing an exemplary process 600 of forming a bonding matrix on a PCB surface. In some embodiments, processing times are reduced compared to processes that use full encapsulation because less resin material is used, leading to reduced curing time.

At step 602, a PCB having SMD LED chips soldered thereon is received and mounted onto a level fixture, where the surface onto which the SMD LED chips are mounted is facing upwards, leveled, and exposed for bonding matrix material to be deposited thereon. In some embodiments, a dam configured to catch excess of the deposited bonding matrix material is installed around one or more perimeter edges of the PCB to prevent overflow onto an outer edge surface of the PCB. In some embodiments, masking is applied to the one or more of the outer edge surfaces of the PCB board to prevent the bonding matrix material from contacting the outer edge surfaces of the PCB.

At step 604, a bonding matrix material is deposited onto the exposed PCB surface at a flow rate that provides substantially even wicking around the perimeter of each LED chip. In some embodiments, the bonding matrix material is a liquid that has a fairly low viscosity that promotes flow around the LED chips and allows for such substantially even wicking as well as desired bonding. In some embodiments, surface tension of the bonding matrix material maintains the material on the PCB surface. In some embodiments, a robotic system deposits the bonding matrix material on the PCB surface via one or more nozzle tips or needle tips that output the material at various locations across the surface of the PCB.

At step 606, the deposited bonding matrix material is optionally degassed to remove bubbles that may be present. In some embodiments, degassing is performed by exposing the PCB and uncured bonding matrix material to a vacuum or reduced pressure conditions, for example by placing the assembly in a vacuum chamber. Degassing may not be required with bonding matrix materials having very low viscosity, as a lower viscosity material will have reduced air entrapment.

At step 608, deposited bonding matrix material is optionally wicked such that the matrix has a specified thickness on the PCB. In some embodiments, a horizontal roller is applied to the PCB surface having a deposited bonding matrix material. The roller wicks excess material from the surface such that each SMD LED chip is only partially encapsulated by the material. In some embodiments, the PCB is fed via a conveyor to the roller, where the speed at which the PCB is fed by the conveyor to the roller adjusts the amount of material that is wicked. For example, slower speed feeding removes more material. In some embodiments, the conveyor speed is configured such that the PCB feeding speed allows the roller to remove a specified amount of material, resulting in a specified and consistent thickness of the bonding matrix. In other embodiments, a cloth is applied to the PCB surface having a deposited bonding matrix material. The cloth wicks excess material from the surface such that each SMD LED chip is only partially encapsulated by the material. In some embodiments, the cloth may be held in a frame and indexed to the PCB (e.g., aligned with outer edges of the PCB, for example), lowered and placed into position on the PCB to absorb material.

In some embodiments, the thickness of the deposited bonding matrix after wicking is substantially equal to a single value that is about 5% to about 80% of the height of each chip, measured from the surface of the PCB to the vertex of each chip, which forms a substantially uniform thickness across the bonding matrix that is substantially equal to that single value. In some embodiments, the thickness of the deposited bonding matrix after wicking is substantially equal to a single value that is about 40% to about 50% of the height of each chip, measured from the surface of the PCB to the vertex of each chip, which forms a substantially uniform thickness across the bonding matrix that is substantially equal to that single value. In some embodiments, the material covers exposed electrical contacts between each chip and the PCB.

At step 610, the deposited bonding matrix material is optionally degassed. In some embodiments, the degassing removes bubbles that are present underneath LED chips.

At step 612, the PCB with deposited bonding matrix material undergoes a curing process, which results in the PCB having a cured bonding matrix. The curing process is preferably performed while the PCB is held level so that the cured bonding matrix has a substantially uniform thickness across the PCB. In some embodiments, the curing process is a thermal curing process. In other embodiments, the curing process is a light curing process, such as a UV light curing process. In some embodiments, the curing process takes approximately four hours.

It will be apparent to those having skill in the art that many changes may be made to the details of the above-described embodiments without departing from the underlying principles of the invention. The scope of the invention should be determined only from the claims.

1. An electronic display module, comprising:
a printed circuit board (PCB);
an array of light emitting diodes (LEDs) mounted on an outer major surface of the PCB in spaced-apart relation, each of the LEDs having a light-emitting outer portion facing away from the PCB and located at a height above the outer major surface of the PCB; and
a bonding matrix disposed on the outer major surface of the PCB between the adjacent LEDs, the bonding matrix having a thickness that is less than the heights of the outer portions of the LEDs, so as to not cover the light-emitting outer portions of the LEDs, the bonding matrix adhering to the PCB and the LEDs to secure the LEDs in place on the PCB.

2. The electronic display module of claim 1, wherein the bonding matrix is a cured epoxy resin.

3. The electronic display module of claim 1, wherein the bonding matrix has a substantially uniform thickness across the entire PCB.

4. The electronic display module of claim 3, wherein the bonding matrix has an outer surface with a planarity less than 0.01 inch.

5. The electronic display module of claim 3, wherein the thickness of the bonding matrix varies less than 10% across the entire PCB.

6. The electronic display module of claim 1, wherein the thickness of the bonding matrix is between 5% and 80% of the heights of the LEDs.

7. The electronic display module of claim 1, wherein the bonding matrix provides adhesion between adjacent LEDs.

8. The electronic display module of claim 1, wherein the PCB includes outer edge surfaces bordering the outer major surface and the outer edge surfaces are substantially devoid of the bonding matrix.

9. The electronic display module of claim 1, wherein the bonding matrix is degassed.

10. The electronic display module of claim 1, wherein the array of LEDs includes rows and columns of LEDs spaced by a pitch distance in the range of between 0.7 mm to 2.5 mm.

11. The electronic display module of claim 1, wherein the LEDs are SMD LEDs with electrical contacts soldered to contacts on the outer major surface of the PCB, and the bonding matrix encapsulates the electrical contacts of the SMD LEDs.

12. The electronic display module of claim 1 wherein the bonding matrix includes a colorant.

13. A display system including an array of multiple display cabinets, each display cabinet formed of multiple display modules according to claim 1.

14. A method of making a ruggedized display module, comprising:
providing a display module including a printed circuit board (PCB) having an array of light-emitting diodes (LEDs) mounted on an outer major surface of the PCB in spaced-apart relation, each of the LEDs having a light-emitting outer portion facing away from the PCB and located at a height above the outer major surface of the PCB;
depositing a bonding matrix material onto the outer major surface of the PCB between the LEDs to a thickness that is at least 5% of the height of the outer portions of the LEDs and less than the heights of the outer portions of the LEDs, so as to not cover the light-emitting outer portions of the LEDs; and
curing the bonding matrix material to form a bonding matrix that is adhered to the PCB and the LEDs.

15. The method of claim 14, wherein the bonding matrix material includes one of a resin, a polymer, an epoxy, and a urethane.

16. The method of claim 14, wherein the bonding matrix material includes a thinner or reducing agent.

17. The method of claim 14, wherein the bonding matrix material includes a colorant.

18. The method of claim 14, further comprising degassing the bonding matrix material before curing the bonding matrix material.

19. The method of claim 14, further comprising wicking excess bonding matrix material from the outer major surface of the PCB.

20. The method of claim 14, wherein the step of curing the bonding matrix material includes applying thermal energy, an additive, and/or ultraviolet light.

21. The method of claim 14, wherein the step of depositing the bonding matrix material includes dispensing the bonding matrix material via multiple needles or nozzles positioned between adjacent ones of the LEDs.

22. The method of claim 14, further comprising masking outer edge surfaces of the PCB before depositing the bonding matrix material.

23. The method of claim 14, further comprising leveling the PCB so that the cured bonding matrix has a substantially uniform thickness.

24. The method of claim 14, wherein the step of depositing the bonding matrix material includes depositing an amount of the bonding matrix material such that the cured bonding matrix encapsulates electrical contacts of the LEDs and has a thickness between 5% and 80% of the height of the outer portions of the LEDs.
